(19) United States
(12) Patent Application Publication
(10) Pub. No.: US 2021/0050323 A1
(43) Pub. Date: Feb. 18, 2021

(54) ELECTRODE CONNECTION ELEMENT, LIGHT-EMITTING DEVICE COMPRISING SAME, AND METHOD FOR PRODUCING LIGHT-EMITTING DEVICE

(71) Applicant: JUSUNG ENGINEERING CO., LTD., Gwangju-Si, Gyeonggi-Do (KR)

(72) Inventors: Jung Bae KIM, Gwangju-Si, Gyeonggi-Do (KR); Min Jong KEUM, Gwangju-Si, Gyeonggi-Do (KR); Young Tae YOON, Ansan-Si, Gyeonggi-Do (KR); Kyung Guk LEE, Seoul (KR)

(21) Appl. No.: 16/963,503

(22) PCT Filed: Feb. 7, 2019
(86) PCT No.: PCT/KR2019/001549

§ 371 Date: Jul. 20, 2020

(30) Foreign Application Priority Data
Feb. 9, 2018 (KR) 10-2018-0016200

(51) Int. Cl. H01L 23/00; H01L 27/32

(52) U.S. Cl. CPC H01L 24/73; H01L 24/72; H01L 24/92; H01L 27/3276; H01L 2224/16225; H01L 24/81; H01L 24/16; H01L 2224/73201; H01L 2224/9212; H01L 24/90

(57) ABSTRACT

The present disclosure relates to an electrode connection element, a light emitting apparatus including the same, and a method for manufacturing the light emitting apparatus, and more particularly, to an electrode connection element, a light emitting apparatus including the same, and a method for manufacturing the light emitting apparatus, which are for electrically connecting an electrode terminal and an external drive circuit.

An electrode connection element according to an exemplary embodiment includes: an upper connection member coming into contact with an upper surface of an electrode terminal formed on a substrate; a lower connection member configured to support a lower surface of the substrate; a connection member configured to connect the upper connection member and the lower connection member to each other.

### TECHNICAL FIELD

The present disclosure herein relates to an electrode connection element, a light-emitting device comprising same, and a method for producing the light-emitting device, and more particularly, to an electrode connection element, a light-emitting device comprising same, and a method for producing the light-emitting device, which are for electrically connecting an electrode terminal and an external drive circuit.

### BACKGROUND ART

Light emitting apparatuses means devices in which an electrical signal is converted into infrared or light using the characteristics of a compound semiconductor and which are used for transmitting or receiving signals or used as light sources.

According to rapid advancement in technology of visually expressing electrical signals, research and development, such as reduction in thickness, weight, and power consumption, for exhibiting superior characteristics of light emitting devices, have been intensively carried out. Among these, organic light emitting apparatuses are being used for various application products such as illumination and displays which can have reduced thicknesses and be bent by using self-light emitting elements.

Such a light emitting apparatus emits light in response to an electrical signal applied from an external drive circuit.

In order to apply an electrical signal to a light emitting apparatus from an external drive circuit, a film-on-glass (FOG) bonding method is generally used. The FOG bonding method refers to a method in which: an anisotropic conductive film (ACF) in which conductive particles are distributed in an adhesive resin film is attached to an electrode provided on glass; a flexible printed circuit board (FPCB) is arranged on the anisotropic conductive film and is pressed with an appropriate pressure; and thus, the flexible printed circuit board and the electrode provided on the glass are electrically connected.

However, a method for applying an electrical signal using such an anisotropic conductive film was constituted by a plurality of processes, and thus, there was a limitation in that work time consumed for a bonding process increased and productivity and work efficiency decreased.

### RELATED ART DOCUMENTS

(Patent document 1) KR10-2004-0085897 A

### DISCLOSURE

### Technical Problem

The present disclosure herein relates to an electrode connection element, a light emitting apparatus including the same, and a method for manufacturing the light emitting apparatus which are capable of electrically connecting the electrode terminal and an external drive circuit reliably through a simplified process.

### Technical Solution

In accordance with an exemplary embodiment, an electrode connection element includes: an upper connection member coming into contact with an upper surface of an electrode terminal formed on a substrate; a lower connection member configured to support a lower surface of the substrate; a connection member configured to connect the upper connection member and the lower connection member to each other; and an elastic member provided between the substrate and the lower connection member and configured to maintain a contact between an upper surface of the electrode terminal and the upper connection member.

The electrode terminal may be formed of a conductive nonmetal material, and the upper connection member may be formed of a conductive metal material.

The connection member may include a first connection member and a second connection member which are formed by being respectively bent from both ends of the upper connection member, and the lower connection member may include a first lower connection member and a second lower connection member which are respectively bent from the first connection member and the second connection member.

The first lower connection member and the second lower connection member may be formed by being bent in a direction in which the first connection member and the second connection member face each other, and the elastic member may be supported on the first lower connection member and the second lower connection member and press the substrate.

The elastic member may be formed so that a central portion thereof is curved to protrude toward a lower surface of the substrate.

The upper connection member may include a plurality of protrusion portions protruding from a bottom surface thereof.

The connection member may include a bolt and a nut, or a rivet.

In accordance with another exemplary embodiment, a light emitting apparatus includes: a substrate having an active region and an inactive region; a light emitting element formed on the active region; and an electrode connection element formed on the inactive region and elastically supported by and coupled to the substrate so as to apply power to the light emitting element.

The light emitting element may include an electrode terminal extending onto the inactive region, and one side of the electrode connection element may come into contact with the electrode terminal, and the other side of the electrode connection element may come into contact with the substrate.

The electrode connection element may be coupled by passing through the substrate.

The electrode connection element may be coupled to one side surface of the substrate

In accordance with an exemplary embodiment, a method for manufacturing a light emitting apparatus includes: preparing a substrate having an active region and an inactive region; forming a light emitting element on the active region; and forming, on the inactive region, an electrode connection element elastically supported by the substrate and configured to apply power to the light emitting element.

The forming of the electrode connection element may include: forming a through hole passing through the substrate; and fixing the electrode connection element through the through hole.

The fixing of the electrode connection element may include: providing, on the substrate, a plate member including a horizontal portion and vertical portions each bent from both ends of the horizontal portion; providing an elastic member formed under the substrate so that a central portion thereof is curved toward a bottom surface of the substrate; inserting the vertical portions through the through hole; and inwardly bending the vertical portions exposed from a lower surface of the substrate so as to support the elastic member.

The method for manufacturing a light emitting apparatus may further include soldering, onto the electrode connection element, a wiring line for connecting the electrode connection element to an external drive circuit.

### Advantageous Effects

According to an electrode connection element, a light emitting apparatus including the same, and a method for manufacturing the light emitting apparatus of exemplary embodiments, an electrode terminal may be electrically connected to an external drive circuit even without using an anisotropic conductive film, so that manufacturing costs may be reduced, and productivity may thereby be improved.

In addition, an electrode connection element for applying power to a light emitting element is physically fixed so as to be supported by the substrate, and an external drive circuit is connected to the electrode connection element, so that a bonding process for electrical connection to the external drive circuit may be simplified, and the configuration of the apparatus may be simplified.

Furthermore, when the electrode terminal is provided on a flexible substrate, couplability to the substrate may be improved despite repetitive deformation of the flexible substrate, and thus, the electrical connection characteristic with an external drive circuit and the stability may be improved.

### BRIEF DESCRIPTION OF THE DRAWINGS

FIG. 1 is a view showing a state in which an external drive circuit is connected to a typical light emitting apparatus;

FIG. 2 is a schematic view showing a light emitting apparatus in accordance with an exemplary embodiment;

FIG. 3 is a schematic view showing an electrode connection element in accordance with an exemplary embodiment;

FIG. 4 is a schematic view showing an electrode connection element in accordance with another exemplary embodiment;

FIGS. 5 to 9 are views sequentially showing a method for manufacturing a light emitting apparatus in accordance with an exemplary embodiment; and

FIGS. 10 to 12 are views sequentially showing a method for manufacturing a light emitting apparatus in accordance with another exemplary embodiment.

### DETAILED DESCRIPTION

Hereinafter, exemplary embodiments will be described in detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. In the drawings, like reference numerals refer to like elements throughout.

It will be understood that it is referred to as being “on,” “connected to”, “stacked”, or “coupled to” another element, it may be directly on, connected, stacked, or coupled to the other element or intervening elements may be present.

Spatially relative terms, such as “above” or “upper” and “below” or “lower” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. Like reference numerals refer to like elements throughout.

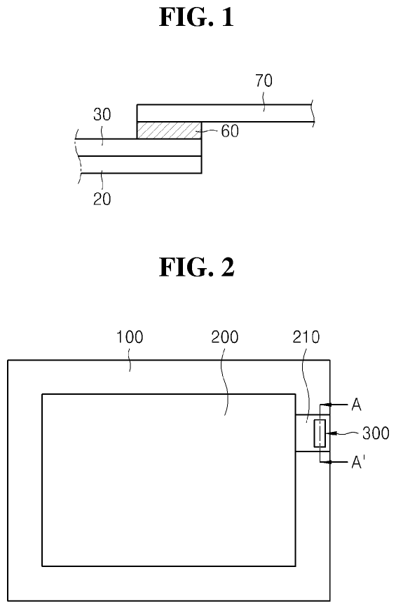

FIG. 1 is a view showing a state in which an external drive circuit is connected to a typical light emitting apparatus.

As shown in FIG. 1, in order to electrically connect a light emitting element to an external drive circuit, typical light emitting apparatuses used an anisotropic conductive film (ACF) 60 having conductive particles distributed in an adhesive film.

That is, the typical light emitting apparatuses used a method in which an anisotropic conductive film 60, having conductive particles distributed in an adhesive film, was adhered onto an electrode terminal 30 extending from an electrode layer included in the light emitting element, a flexible printed circuit board (FPCB) 70 was disposed on the anisotropic conductive film and was pressed against a substrate 20, and thus, the flexible printed circuit board 70 was electrically connected to the electrode terminal 30 included in the light emitting element.

This is because the electrode terminal 30 is formed of a conductive nonmetal material, and the conductive nonmetal material can not be connected to an external drive circuit, for example, an external electrical wire or a printed circuit board through soldering. That is, a metal material and another metal material can be joined and electrically connected to each other by soldering using solder or the like, while as such a soldering method can not be used when joining a nonmetal material and a metal material.

However, an electrical signal application method using such an anisotropic conductive film 60 may have limitations in that an adhesive resin of the anisotropic conductive film 60 is melted and flows during a heat pressing process, and at this point, conductive particles move together with the resin flow, so that an external drive circuit is not electrically connected, or undesirable short circuit may occur between electrodes.

In addition, there may be a limitation in that a bonding process is performed as a separate process using the ACF 60, and each of loading, pre- and main-bonding, and unloading processes are sequentially performed, so that a work time for bonding process increases and thus productivity and work efficiency decreases.

Thus, an electrode connection element in accordance with an exemplary embodiment proposes a technical feature in which an external drive circuit and an electrode terminal may be electrically connected without using an ACF. Hereinafter, a configuration will be exemplarily described in which an electrode connection element in accordance with an exemplary embodiment electrically connects an external drive circuit and an electrode terminal of a light emitting element provided on a substrate. However, the electrode connection element may, of course, be applied not only to an electrode terminal of a light emitting element, but also to various electrical elements to which power is connected from an external drive circuit.

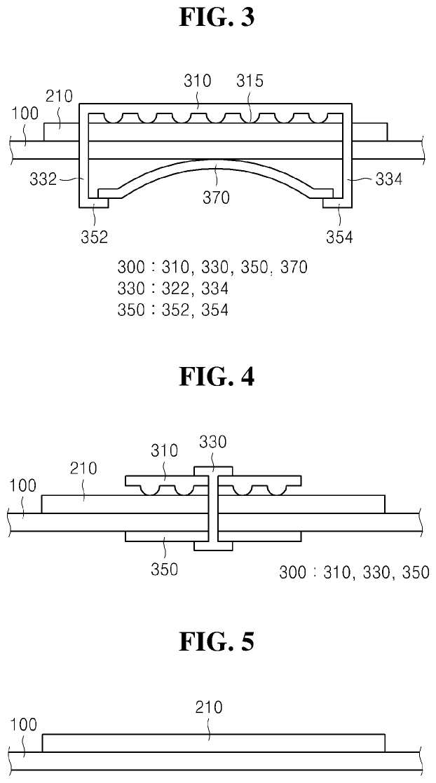

FIG. 2 is a schematic view showing a light emitting apparatus in accordance with an exemplary embodiment. In addition, FIG. 3 is a schematic view showing an electrode connection element in accordance with an exemplary embodiment, and FIG. 4 is a schematic view showing an electrode connection element in accordance with another exemplary embodiment.

Referring to FIGS. 2 to 4, an electrode connection element 300 in accordance with an exemplary embodiment includes: an upper connection member 310 coming into contact with an upper surface of an electrode terminal 210 formed on a substrate 100; a lower connection member 350 which supports a lower surface of the substrate 100; and a connection member 330 which connects the upper connection member 310 and the lower connection member 350 to each other.

In addition, a light emitting apparatus in accordance with an exemplary embodiment is configured to include the electrode connection element 300, and more particularly, includes: a substrate 100 having an active region and an inactive region; a light emitting element 200 provided on the active region; and an electrode connection element 300 which are provided on the inactive region and are supported and coupled on the upper and lower sides of the substrate 100 so as to apply power to the light emitting element 200.

Various insulating substrates may be used for the substrate 100. In addition, in order to achieve a flexible display, spotlighted recently as a new technology in the display field, the substrate 100 may be formed as a flexible transparent substrate. In this case, the substrate 100 may be formed by using a polymer plastic having superior heat resistance such as polyethersulphone (PES), polyacrylate (PAR), polyehterimide (PEI), polyethylenenapthalate (PEN), or polyehtyleneterepthalate (PET).

In addition, the substrate 100 may be a thin film and be formed to have a thickness of approximately 0.1 mm or smaller, favorably, approximately 50 μm to approximately 100 μm. As such, when the substrate 100 is formed as a flexible, thin, transparent substrate of plastic or the like, a flexible illumination device and a flexible display, which are next-generation display devices not damaged even when folded or rolled like paper, may be implemented.

The substrate 100 has an active region and an inactive region. Here, on the substrate 100, the active region means a region, in which a light emitting element 200 is formed and an illumination or display function is performed, and the inactive region means a region, which is other than the active region and to which an external drive circuit is electrically connected.

The light emitting element 200 is formed on the active region. Here, the light emitting element 200 may be an organic light emitting element which uses a self-emission phenomenon and includes an organic compound layer. Hereinafter, an example in which the light emitting element 200 includes an organic light emitting element, but the light emitting element 200 is not limited thereto, and various structures may, of course, be applied which are provided on the active region of the substrate 100 and emit light.

The light emitting element 200 may include an electrode layer formed on the substrate 100; an organic compound layer formed on the electrode layer; and a conductive layer formed on the organic compound layer.

The electrode layer and the conductive layer may respectively be a cathode electrode and an anode electrode for supplying electrons and holes to the organic compound layer, and when the light emitting element 200 is used for a display device, the electrode layer and the conductive layer may respectively extend so as to form data lines and scan lines. In this case, the electrode terminal 210 may extend from the electrode layer or the conductive layer and be electrically connected to a thin film transistor (not shown) provided on the substrate 100.

The electrode terminal 210 may be formed so as to extend from the active region to the inactive region on the substrate 100. The electrode terminal 210 is mainly formed so as to extend from the electrode layer of the light emitting element 200 toward one side, but, of course, the conductive layer may also be formed so as to extend to the other side of the light emitting element 200 to form the electrode terminal 210. Here, the conductive layer formed on the organic compound layer is not necessarily formed of a conductive nonmetal material when light is emitted toward the substrate 100 from the organic light emitting layer. However, when the conductive layer is formed of a conductive nonmetal material, a limitation occurs in that the electrode terminal 210 extending from the conductive layer may not be connected to an external drive circuit by soldering, and thus, the exemplary embodiment may, of course, be also applied to this case in the same way.

The electrode layer may be formed of a transparent conductive material such as indium tin oxide (ITO), indium zinc oxide (IZO), and indium tin zinc oxide (ITZO), and accordingly, so that light generated from the organic compound layer formed on the electrode layer may be allowed to be emitted to the lower side of the substrate 100 without interference of the electrode layer.

The organic compound layer is formed on the electrode layer. Although not shown, the organic compound layer may be formed by laminating a hole injection layer, a hole transport layer, a light emitting layer, an electron transport layer, and an electron injection layer. In the organic compound layer, when a drive signal is applied from an external drive circuit, electrons and holes are discharged from the respective electrode layer and the conductive layer, and the discharged electrons and holes emit visible light while recombined inside the light emitting layer. At this point, the generated visible light may be emitted to the lower side of the substrate 100 through the electrode layer formed of a transparent conductive material, and functions to illuminate an target object or display a predetermine picture or image.

The electrode connection element 300 may be formed on the inactive region of the substrate 100, and be supported on the upper and lower sides of the substrate 100 so as to apply power to the light emitting element 200. That is, the electrode connection element 300 comes into contact with the electrode terminal 210 extending from the electrode layer onto the inactive region and is electrically connected to the electrode layer, and the electrode connection element 300 has a structure of being supported on the upper and lower sides of the substrate 100 and physically connected to the electrode terminal 210 and the substrate 100.

As described above, an electrode connection element 300 includes: an upper connection member 310 coming into contact with an upper surface of an electrode terminal 210 formed on the substrate 100; a lower connection member 350 which supports a lower surface of the substrate 100; and a connection member 330 which connects the upper connection member 310 and the lower connection member 350 to each other. That is, the upper connection member 310 is located over the substrate 100, and more specifically, on the electrode terminal 210 extending to the inactive region of the substrate 100, and comes into contact with and electrically connected to the electrode terminal 210. To this end, the upper connection member 310 may be formed of a conductive metal material. In addition, the lower connection member 350 is located under the substrate 100 and presses and supports the lower surface of the substrate 100. Here, the connection member 330 connects the upper connection member 310 and the lower connection member 350 to each other, and thus, the electrode connection element 300 may be supported on and coupled to the upper and lower sides of the substrate.

As such, the electrode connection element 300 comes into contact with the electrode terminal 210 on the substrate 100 by means of the upper connection member 310, and may pass through the substrate 100 so as to press and support the lower surface of the substrate 100 to be coupled to the substrate 100 and the electrode terminal 210 by means of the lower connection member 350. In addition, although not shown, the electrode connection element 300 may, of course, be also coupled to one side surface of the substrate 100, that is, to an end portion of one side surface of the substrate 100 such that the connection member 330 is formed by being bent downward from one end of the upper connection member 310, and that the lower connection member 350 is formed to extend from the lower end of the connection member 330 in a direction toward the upper connection member 310. Hereinafter, an embodiment in which the electrode connection element 300 passes through the substrate 100 and is coupled to the substrate 100 and the electrode terminal 210, but the exemplary embodiment is not limited thereto, and the electrode connection element may, of course, be applied to various structures in which the electrode connection element is electrically connected to the electrode terminal 210 and is supported on and coupled to the upper and lower sides of the substrate 100.

As shown in FIG. 3, the electrode connection element 300 in accordance with an exemplary embodiment may include: an upper connection member 310 coming into contact with the upper surface of an electrode terminal 210; a lower connection member 350 which supports the lower surface of a substrate 100; and a connection member 330 which connects the upper connection member 310 and the lower connection member 350 to each other, wherein the connection member 330 may include a first connection member 332 and a second connection member 334 which are respectively formed by being bent from both ends of the upper connection member 310, and the lower connection member 350 may include a first lower connection member 352 and a second lower connection member 354 which are respectively formed by being bent from the first connection member 332 and the second connection member 334.

Here, through holes may be formed in the substrate 100 in order to couple the connection members. In general, when light is emitted from an organic light emitting layer toward the substrate 100, a transparent glass substrate may be used as the substrate 100. However, in a light emitting apparatus in accordance with an exemplary embodiment, in order to couple the electrode connection element 300, it is necessary to form through holes in the substrate 100. Thus, it is desirable to use a flexible transparent substrate compared to a glass substrate which is more likely to generate a crack when forming through holes. In addition, the through holes may be formed in the substrate 100 by laser processing or the like, and in FIG. 3, this is an example in which two through holes are provided so as to pass through both the electrode terminal 210 and the substrate 100 by laser processing or the like. However, when the electrode connection element 300 is formed so that the first connection member 332 and the second connection member 334 are disposed outside both ends of the electrode terminal 210, it is of course unnecessary to provide a through hole in the electrode terminal 210.

Here, the electrode connection element 300 may be formed by processing a plate member which is formed by using a plate-like member and includes a horizontal portion and vertical portions respectively bent downward from both ends of the horizontal portion. That is, in a plate member which has: a horizontal portion corresponding to the upper connection member 310; and vertical portions respectively bent downward from both ends of the horizontal portion, the first connection member 332 and the first lower connection member 352 are formed by bending the vertical portions bent from one end of the horizontal portions, and the second connection member 334 and the second lower connection member 354 are formed by bending the vertical portions bent from the other end of the horizontal portions. Thus, the electrode connection element 300 may be formed which includes the upper connection member 310 coming into contact with the upper surface of the electrode terminal 210, the lower connection member 350 which supports the lower surface of the substrate 100, and the connection member 330 which connects the upper connection member 310 and the lower connection member 350 to each other. This electrode connection element 300 may be formed in one body, and be formed of a metal material having high conductivity. In addition, the upper connection member 310 may include a plurality of protrusion portions 315 protruding from a bottom surface thereof. These protruding portions 315 are integrally formed with the upper connection member 310 and improve a contact property between the upper connection member 310 and the electrode terminal 210. The protrusion portions 315 may be formed on the bottom surface of the upper connection member 310 by various methods, such as a method of increasing the roughness of the bottom surface of the upper connection member 310.

In the electrode connection element 300 in accordance with an exemplary embodiment, the first lower connection member 352 and the second lower connection member 354 may be formed by being respectively bent toward outside the first connection member 332 and the second connection member 334, but may also be formed by being respectively bent inward in the direction in which the first connection member 332 and the second connection member 334 face each other. In both cases, the electrode connection element 300 may press the lower surface of the substrate 100 and be supported by the substrate 100 by means of the first lower connection member 352 and the second lower connection member 354, but when the first lower connection member 352 and the second lower connection member 354 are formed by being respectively bent in the direction in which the first connection member 332 and the second connection member 334 face each other, an elastic member 370 may easily be fixed to the lower surface of the substrate 100 between the first lower connection member 352 and the second lower connection member 354.

The elastic member 370 is provided between the substrate 100 and the lower connection member 350, and maintains the contact between the upper surface of the electrode 210 and the upper connection member 310. That is, the elastic member 370 presses the substrate 100 upward from the lower surface, and thus, the electrode connection element 300 is elastically supported by the substrate and the contact between the upper surface of the electrode terminal 210 and the upper connection member 310 may be maintained. In addition, the area of the contact surface on which the upper surface of the electrode terminal 210 is in contact with the upper connection member 310 may be increased by pressing the elastic member 370. That is, the elastic member 370 provides an upward pressing force to the substrate 100, and thus, not only the contact between the upper surface of the electrode terminal 210 and the upper connection member 310 may be maintained, but also the area of the contact surface may also be increased. In addition, when a flexible substrate is used, the contact state between the upper surface of the electrode terminal 210 and the upper connection member 310 may reliably be maintained even when the substrate 100 is folded or rolled.

The elastic member 370 may be provided in various forms of being provided between the substrate 100 and the lower connection member 350 and pressing the substrate 100 upward. However, as described above, when the first lower connection member 352 and the second lower connection member 354 are formed by being bent in the direction in which the first connection member 332 and the second connection member 334 face each other, both ends of the elastic member 370 may also be supported on the first lower connection member 352 and the second lower connection member 354 and press the substrate 100. In addition, the elastic member 370 may be provided so that the central portion thereof is bent to protrude toward the lower surface of the substrate 100 and elastically press the substrate 100 from under. In this case, the elastic member 370 is not necessarily be formed of a conductive metal material, but may rather be formed of an insulating material in order to prevent defects such as short from occurring.

Conversely, as shown in FIG. 4, an electrode connection element 300 in accordance with another exemplary embodiment includes: an upper connection member 310 coming into contact with an upper surface of an electrode terminal 210; a lower connection member 350 which supports a lower surface of the substrate 100; and a connection member 330 which connects the upper connection member 310 and the lower connection member 350 to each other, wherein the connection member 330 may be formed to include a bolt and a nut, or formed by riveting.

Here, through holes may also be formed in the substrate 100 in order to couple the connection members. Accordingly, a flexible, transparent substrate is favorably used for the substrate 100 rather than a glass substrate which is more likely to generate a crack when forming a through hole, and a single through hole may be formed in the substrate 100 or in the substrate and the electrode terminal 210 by laser processing or the like.

Here, the electrode connection element 300 may be formed such that the upper connection member 310 having a through hole is arranged on the electrode terminal 210 and the lower connection member having a through hole is arranged under the substrate 100, and the upper connection member 310 and the lower connection member 350 are fixed by a bolt and a nut or by a rivet. That is, the electrode connection element 300, which includes the upper connection member 310 coming into contact with the upper surface of the electrode terminal 210, the lower connection member which supports the lower surface of the substrate 100, and the connection member 330 which connects the upper connection member 310 and the lower connection member 350 to each other, may be formed such that: a bolt is inserted from over the upper connection member 310 into the upper connection member 310 arranged on the electrode terminal 210 and the lower connection member 350 arranged under the substrate 100, and then a nut is fastened to the bolt exposed from the lower surface of the substrate 100; or such that a rivet is inserted from over the upper connection member 310 and the end portion of the rivet exposed from the lower surface of the substrate 100 is processed. In this case, although not shown, the electrode connection element 300 may, of course, further include an elastic member which is coupled to the bolt or the rivet, exposed from the lower surface of the substrate 100, and presses the substrate 100.

Here, the upper connection member 310 may be formed of a material including a metal material having high conductivity, and may include a plurality of protrusion portions 315 protruding from the bottom surface thereof. In addition, the electrode connection element 300 in accordance with another exemplary embodiment may, of course, further include a washer disposed over the electrode terminal 210 or under the substrate 100 in order to protect the surface of the electrode terminal 210 or the substrate 100 and improve the fastening force between the bolt and nut.

Hereinafter, a method for manufacturing a light emitting apparatus in accordance with an exemplary embodiment will be described in detail. In describing the method for manufacturing a light emitting apparatus in accordance with an exemplary embodiment, the description on the overlapping content described above regarding the light emitting apparatus in accordance with an exemplary embodiment will be omitted.

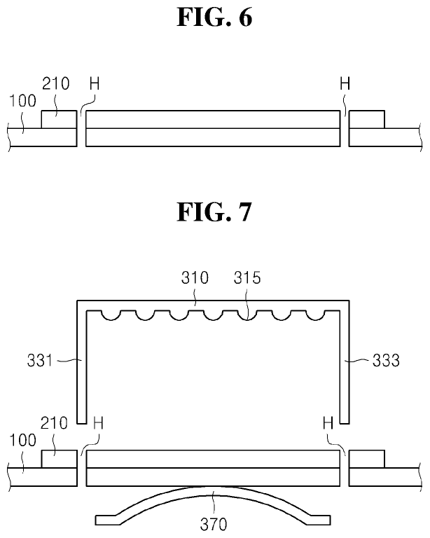

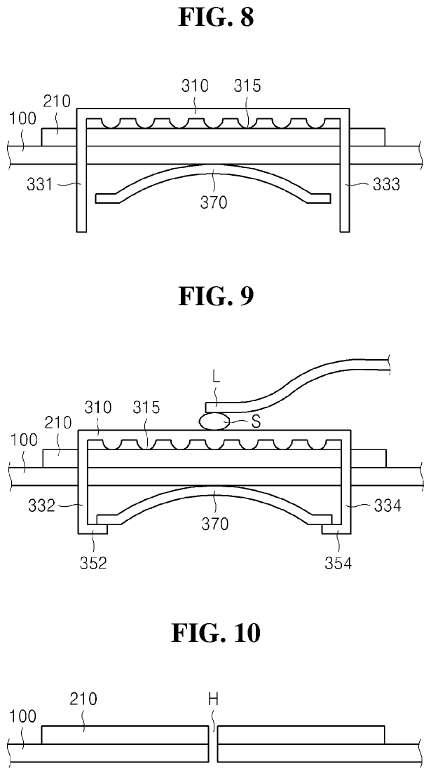

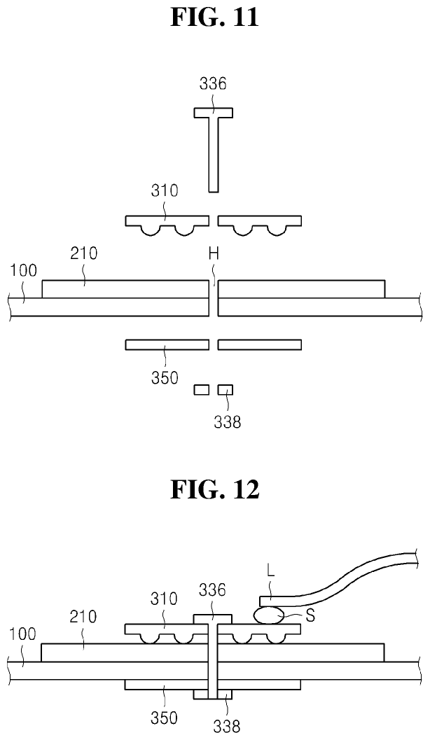

FIGS. 5 to 9 are views sequentially showing a method for manufacturing a light emitting apparatus in accordance with an exemplary embodiment; and FIGS. 10 to 12 are views sequentially showing a method for manufacturing a light emitting apparatus in accordance with another exemplary embodiment.

Referring to FIGS. 5 to 12, a method for manufacturing a light emitting apparatus in accordance with an exemplary embodiment includes: preparing a substrate 100 having an active region and an inactive region; forming a light emitting element 200 on the active region; and forming an electrode connection element 300 which is supported on the upper and lower sides of the substrate on the inactive region so as to apply power to the light emitting element 200.

In the preparing of the substrate 100, a substrate 100 is prepared in which an active region and an inactive region are defined. Here, in order to achieve a flexible display, the substrate 100 may be formed by using a flexible transparent substrate, for example, using a polymer plastic, or may also be formed in a film type.

In the forming of the light emitting element 200 on the active region, the light emitting element 200 is formed inside the active region on the substrate 100, and the light emitting element 200 may be an organic light emitting element including an organic compound layer using a self light emitting phenomenon. In addition, as described above, the light emitting element 200 may include an electrode layer formed on the substrate 100; an organic compound layer formed on the electrode layer; and a conductive layer formed on the organic compound layer. The forming of the light emitting element 200 on the substrate 100 is generally well known, so that a detailed description thereon will be omitted.

In the forming of the electrode connection element 300, an electrode connection element 300 is formed which is for supplying power to the light emitting element 200 and which is supported on the upper and lower sides of the substrate 100 on the inactive region of the substrate 100.

As described above, the electrode terminal 210 may be formed so as to extend from an electrode layer on the active region to the inactive region on the substrate 100. Here, the electrode terminal 210 may be formed of a transparent conductive material such as indium tin oxide (ITO), indium zinc oxide (IZO), and indium tin zinc oxide (ITZO) in the same way as the electrode layer, and accordingly, light generated from the organic compound layer formed on the electrode layer may be allowed to be emitted to the lower side of the substrate 100 without interference of the electrode layer.

Accordingly, in the forming of the electrode connection element 300, the electrode connection element 300 is formed so as to be in contact with and electrically connected to the electrode terminal 210 on the inactive region of the substrate 100. As described above, the electrode connection element 300 includes: an upper connection member 310 coming into contact with an upper surface of the electrode terminal 210; a lower connection member 350 which supports the lower surface of the substrate 100; and a connection member 330 which connects the upper connection member 310 and the lower connection member 350 to each other. Here, the upper connection member 310 is located over the substrate 100, and more specifically, on the electrode terminal 210 extending to the inactive region of the substrate 100, and comes into contact with and electrically connected to the electrode terminal 210. In addition, the lower connection member 350 is located under the substrate 100 and presses and supports the lower surface of the substrate 100. Here, the connection member 330 connects the upper connection member 310 and the lower connection member 350 to each other, and thus, the electrode connection element 300 may be supported on and coupled to the upper and lower sides of the substrate.

This electrode connection element 300 may also be formed such that the connection member 330 is bent downward from an end of the upper connection member 310, and the lower connection member 350 is formed to be extend from the lower ends of the connection member 330 in the direction toward the upper connection member 310 so as to engage with one side surface, that is, a side end of the substrate 100. However, the electrode connection element 300 may come into contact with the electrode terminal 210 by the upper connection member 310 and may pass through the substrate 100 and be coupled to the substrate 100 and the electrode terminal 210 so as to press and support the lower surface of the substrate 100 by the lower connection member 350.

When the electrode connection element 300 is formed so as to pass through the substrate 100 and be coupled to the substrate 100 and the electrode terminal 210, the forming of the electrode connection element 300 may include: forming through holes H passing through the substrate 100; and fixing the electrode connection element 300 through the through holes.

Here, the fixing of the electrode connection element 300 in accordance with an exemplary embodiment may be performed as shown in FIGS. 5 to 9. That is, the fixing of the electrode connection element 300 in accordance with an exemplary embodiment may include: providing a plate member, which includes a horizontal portion and vertical portions 331 and 333 bent downward from both ends of the horizontal portion; inserting the vertical portions 331 and 333 thorough the through holes H; and inwardly bending the vertical portions 331 and 333 exposed from the lower surface of the substrate 100.

That is, in order to fix the electrode connection element 300 in accordance with an exemplary embodiment, in the above-described forming of the through holes H, two through holes are formed at positions corresponding to the respective downwardly bent vertical portions 331 and 333 from both ends of the plate member. These through holes H may be formed only in the substrate 100, or be formed in both the substrate 100 and the electrode terminal 210.

After forming the through holes H in the substrate 100 or in the substrate and the electrode terminal 210, the plate member, which includes the horizontal portion and downwardly bent vertical portions 331 and 333 is bent from both ends of the horizontal portion, is provided above the substrate 100, that is, onto the electrode terminal 210 formed on the substrate. Here, the plate member has the horizontal portion corresponding to the upper connection member 310 and the vertical portions 331 and 333 which are downwardly bent from both ends of the horizontal portion. In addition, a plurality of protrusion portions 315 protruding from the bottom surface of the horizontal portion may be provided on the bottom surface, and as described above, the contact property between the horizontal portion and the electrode terminal 210 may be improved by the protrusion portions.

When the plate member is provided above the electrode terminal 210, each of the vertical portions 331 and 333 are inserted into the through holes H by downwardly pressing the plate member. As such, the inserting of the vertical portions into the respective through holes H by downwardly pressing the plate member is performed by pressing the plate member until the horizontal portion, that is, the upper connection member 310 contacts the upper surface of the electrode terminal 210, and when the upper connection member 310 comes into contact with the upper surface of the electrode terminal 210 and presses the electrode terminal 210 with a predetermined pressure, the vertical portions 331 and 333 exposed from the lower surface of the substrate 100 through the through holes H are bent inward in the respective directions facing each other. Here, the inwardly bending of each of the vertical portions 331 and 333 may be performed so that the vertical portions 331 and 333 press the lower surfaces of the substrate 100, and the connection member 330 and the lower connection member 350 may be formed by the inwardly bending of each of the vertical portions 331 and 333.

In addition, the fixing of the electrode connection element 300 in accordance with an exemplary embodiment may further include: providing an elastic member 370, which is formed to be curved so that the central portion thereof protrudes toward the bottom surface of the substrate 100, under the substrate 100 before the inserting of the vertical portions 331 and 333 through the through holes H. The provided elastic member 370 presses the substrate 100 while both ends thereof are supported by the first lower connection member 352 and the second lower connection member 354 which are formed by the inwardly bending of each of the vertical portions 331 and 333. Accordingly, the electrode connection element 300 is elastically supported by the substrate 100 and elastically presses the substrate 100 from under, and thus, the contact between the upper surface of the electrode terminal 210 and the upper connection member 210 may be maintained. In addition, as described above, the elastic member 370 may elastically press the substrate 100 from under so that the central portion thereof is bent to protrude toward the lower surface of the substrate 100.

In addition, the fixing of the electrode connection element 300 in accordance with another exemplary embodiment may be performed as shown in FIGS. 10 to 12. That is, the fixing of the electrode connection element 300 in accordance with another exemplary embodiment may include: positioning an upper connection member 310 and a lower connection member 350 which are respectively formed on the upper and lower sides of a substrate 100; inserting a bolt 336 through a through hole H from the upper side of the upper connection member 310; and fastening a nut 338 to the bolt 336 exposed from the lower surface of the substrate 100.

That is, in order to fix the electrode connection element 300 in accordance with another exemplary embodiment, in the above-mentioned forming of the through hole H, a single through hole H for inserting the bolt 336, which constitutes the connection member 330, is formed in the substrate 100 or in the substrate 100 and an electrode terminal 210. In addition, the upper connection member 310 and the lower connection member 350 are formed to be penetrated corresponding to the through hole H, the penetratedly formed upper connection member 310 is located on the electrode terminal 210, and the penetratedly formed lower connection member 350 is located under the substrate 100. Here, the upper connection member 310 may include a plurality of protrusion portions 315 protruding from the bottom surface thereof, and as described above, the contact property between the upper connection member 310 and the electrode terminal 210 may be improved by the protrusion portions.

As such, when the upper connection member 310 and the lower connection member 350, which are formed to be penetrated on the upper and lower sides of the substrate 100, are positioned, the bolt 336 is inserted through the through hole H from over the upper connection member 310. The bolt 336 is inserted until one end portion thereof is exposed from the lower surface of the substrate 100, and when the one end portion is exposed from the lower surface of the substrate 100, the nut 338 may be fastened to the one end portion of the bolt 336. The nut 338 may be fastened so that the upper connection member 310 comes into contact with and presses the upper surface of the electrode terminal 210 and the lower connection member 350 presses the lower surface of the substrate 100 by means of the bolt 336. Such connection between the upper connection member 310 and the lower connection member 350 may, of course, be also performed by inserting a rivet (not shown) from over the upper connection member 310 and processing the end portion of the rivet exposed from the lower surface of the substrate 100. In accordance with another exemplary embodiment, the connection member 330 may be formed by means of the bolt 336 and the nut 338, or a rivet, and thus, the electrode connection member 330 may be formed which includes: the upper connection member 310 coming into contact with the upper surface of the electrode terminal 210; the lower connection member 350 which supports the lower surface of the substrate 100; and the connection member 330 which connects the upper connection member 310 and the lower connection member 350. In this case, as described above, the electrode connection element 300 may, of course, further include an elastic member which is coupled to the bolt or the rivet, exposed from the lower surface of the substrate 100, and presses the substrate 100.

When the electrode connection element 300 is formed on the inactive region of the substrate 100 by the above-described process, the light emitting element 200 is electrically connected to an external circuit by the electrode connection element 300. That is, the method for manufacturing the light emitting apparatus in accordance with an exemplary embodiment may further include soldering, onto the electrode connection element 300, a wiring line L for connection to an external circuit. As described above, the electrode connection element 300, more specifically, the upper connection member 310 included in the electrode connection element 300 includes a metal material having high conductivity. Therefore, the wiring line L for connection with an external drive circuit, for example, external electrical line or a printed circuit board, may be electrically connected to the electrode connection element 300 through soldering S.

As such, in accordance with an electrode connection element, a light emitting apparatus including the same, and a method for manufacturing the light emitting apparatus of exemplary embodiments, the electrode terminal 210 may be electrically connected to an external drive circuit even without using an anisotropic conductive film, so that manufacturing costs may be reduced, and productivity may thereby be improved.

In addition, the electrode connection element 300 for applying power to a light emitting element 200 is physically fixed so as to be supported by the substrate 100, and an external drive circuit is connected to the electrode connection element 300, so that a bonding process for electrical connection to the external drive circuit may be simplified, and the configuration of the apparatus may be simplified.

Furthermore, when an electrode terminal 210 is formed on a flexible substrate, couplability to the substrate may be improved despite repetitive deformation of a flexible substrate, and thus, the electrical connection characteristic with an external drive circuit and the stability may be improved.

While preferable exemplary embodiments have been described and illustrated using specific terms, such terms were merely used to explain the exemplary embodiments, and it is obvious that exemplary embodiments and used terms may be variously modified and changed without departing from the spirit and scope as defined by the following claims. Such variously modified embodiments should not be interpreted separated from the spirit and scope of the present disclosure, and but to be included in the scope of the present disclosure.

What is claimed is:

1. An electrode connection element comprising:
an upper connection member coming into contact with an upper surface of an electrode terminal formed on a substrate;
a lower connection member configured to support a lower surface of the substrate;
a connection member configured to connect the upper connection member and the lower connection member to each other; and
an elastic member provided between the substrate and the lower connection member and configured to maintain a contact between the upper surface of the electrode terminal and the upper connection member.

2. The electrode connection element of claim 1, wherein
the electrode terminal is formed of a conductive nonmetal material, and
the upper connection member is formed of a conductive metal material.

3. The electrode connection element of claim 1, wherein
the connection member comprises a first connection member and a second connection member which are formed by being respectively bent from both ends of the upper connection member, and
the lower connection member comprises a first lower connection member and a second lower connection member which are respectively bent from the first connection member and the second connection member.

4. The electrode connection element of claim 3, wherein
the first lower connection member and the second lower connection member are formed by being bent in a direction in which the first connection member and the second connection member face each other, and
the elastic member is supported on the first lower connection member and the second lower connection member and presses the substrate.

5. The electrode connection element of claim 4, wherein the elastic member is formed so that a central portion thereof is curved to protrude toward the lower surface of the substrate.

6. The electrode connection element of claim 1, wherein the upper connection member comprises a plurality of protrusion portions protruding from a bottom surface thereof.

7. The electrode connection element of claim 1, wherein the connection member comprises a bolt and a nut, or a rivet.

8. A light emitting apparatus comprising:
a substrate having an active region and an inactive region;
a light emitting element formed on the active region; and
an electrode connection element formed on the inactive region and elastically supported by and coupled to the substrate so as to apply power to the light emitting element.

9. The light emitting apparatus of claim 8, wherein
the light emitting element comprises an electrode terminal extending onto the inactive region,
one side of the electrode connection element comes into contact with the electrode terminal, and
the other side of the electrode connection element comes into contact with the substrate.

10. The light emitting apparatus of claim 8, wherein the electrode connection element is coupled by passing through the substrate.

11. The light emitting apparatus of claim 8, wherein the electrode connection element is coupled to one side surface of the substrate.

12. A method for manufacturing a light emitting apparatus comprising:
preparing a substrate having an active region and an inactive region;
forming a light emitting element on the active region; and
forming, on the inactive region, an electrode connection element elastically supported by the substrate and configured to apply power to the light emitting element.

13. The method of claim 12, wherein the forming of the electrode connection element comprises:
forming a through hole passing through the substrate; and
fixing the electrode connection element through the through hole.

14. The method of claim 13, wherein the fixing of the electrode connection element comprising:
providing, on the substrate, a plate member comprising a horizontal portion and vertical portions each bent from both ends of the horizontal portion;
providing an elastic member formed under the substrate so that a central portion thereof is curved toward a bottom surface of the substrate;
inserting the vertical portions through the through hole; and
inwardly bending the vertical portions exposed from the lower surface of the substrate so as to support the elastic member.

15. The method of claim 12, further comprising soldering, onto to the electrode connection element, a wiring line for connecting the electrode connection element to an external drive circuit.
